(19) United States
(12) Patent Application Publication
(10) Pub. No.: US 2004/0262719 A1
(43) Pub. Date: Dec. 30, 2004

(54) Lead frame for semiconductor packages

(75) Inventors: Kazumitsu Seki, Nagano-shi (JP); Muneaki Kure, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano (JP)

(21) Appl. No.: 10/876,580

(22) Filed: Jun. 28, 2004

(30) Foreign Application Priority Data
Jun. 30, 2003 (JP) 2003-186421

(51) Int. Cl. H01L 23/495

(52) U.S. Cl. 257/666

(57) ABSTRACT

A lead frame, for semiconductor devices, provided with at least internal lead portions and external lead portions, the lead frame comprising: a base material of the lead frame consisting of copper or copper alloy; Pd or Pd alloy plated layers formed, on all surfaces or on at least the internal or external lead portions, through plated-under layers; and the plated under layers consisting of non-ferromagnetic metal in place of Ni plated layer. Ag, Sn, Au or Zn plated layer may be preferably used as the non-ferromagnetic metal. Otherwise, Sn—Ag or Sn—Zn alloy plated layer may also be preferably used as the non-ferromagnetic metal.

### BACKGROUND OF THE INVENTION

1. Field of the Invention

The present invention relates to a lead frame for semiconductor packages and, more specifically, to a lead frame for semiconductor packages using copper or a copper alloy as a base material.

2. Description of the Related Art

Lead frames for semiconductor packages dealing with high-speed signals use copper or a copper alloy as a base material after taking electric properties into consideration. The lead frames using copper or the copper alloy are often provided with bonding portions plated with a noble metal such as silver from the standpoint of improving a wire-bonding property (see, for example, EP 1094519A1).

In the case of the lead frame using copper or the copper alloy as the base material and being partly plated with a noble metal such as silver, a solder film is often formed on the external leads of the lead frame to improve the soldering property of the external leads.

From the standpoint of environmental protection in recent years, however, Pb-free mounting, or bonding with no Pb, is now becoming main-stream. As lead frames for semiconductor packages that can be favorably used for the mounting, it has been increasingly demanded to provide a base material of copper or a copper alloy plated with Pd or a Pd alloy. The lead frame plated with Pd or a Pd alloy has all surfaces of the lead frame plated with Pd or a Pd alloy, without requiring cumbersome operation such as partly plating the lead frame with a noble metal, and offers such advantages as favorable wire-bonding property and solder wettability.

The lead frame is heated when a semiconductor element is attached by die-bonding to the die-pad, when the electrodes of semiconductor element are wire-bonded to the internal leads, or when the semiconductor element is molded with a resin. Due to the heating, however, copper in the base material thermally diffuses to the surface of the lead frame, and the thus-diffused copper undergoes the oxidation to greatly deteriorate the wettability by the solder when actually being mounted on a board. In order to improve the adhesion to the Pd layer by preventing the diffusion of copper in the Pd lead frame which is now becoming the main-stream and to improve the heat resistance and corrosion resistance, therefore, the surface of the copper substrate is plated with Ni, then, with Pd and, further, is flash-plated with Au. The Au flash-plating is to form a thin Au layer on the surface of the Pd layer, and works to protect the Pd layer, prevent the Pd layer from oxidizing and maintain the soldering property of the Pd layer.

FIG. 3 is a plan view of a lead frame preferably used as a lead frame for semiconductor packages. The lead frame 20 has external lead portions 22, internal lead portions 24, and a die-pad portion 26 defining an element mount on which a semiconductor, such as IC, element (not shown) is to be mounted. These portions are connected to rails 30, 30 by means of support bars 28 and dam bars 32.

In a process of manufacturing semiconductor devices, the lead frame 20 basically made of copper or copper alloy, as the base material, is plated with metal layers, as will be described later in detail. Then, a semiconductor element or chip (not shown) is mounted on the die-pad 26 by a die-attaching or a die-bonding step, the electrodes of the semiconductor element are electrically connected to the internal leads 24 by wires (not shown) by wire-bonding step, and then the semiconductor element, the internal leads 24 and wires are sealed with resin (not shown) and, thus, a semiconductor device is obtained.

The semiconductor device thus obtained can be mounted on any circuit or wiring board (not shown) by a reflow step using the external leads 22.

FIG. 4 illustrates a conventional plating constitution on the lead frame having an Ni-plated layer formed under a Pd-plated layer, wherein reference numeral 10 denotes a base material of copper or a copper alloy, 11 denotes the Ni-plated layer, 14 denotes the Pd-plated layer, and 16 denotes an Au flash-plated layer. The Ni-plated layer 11 has a thickness of 0.2 to 2.0 μm, the Pd-plated layer 14 has a thickness of 0.001 to 0.10 μm, and the Au-plated layer 16 has a thickness of 0.001 to 0.03 μm.

In recent years, however, it is a trend that the semiconductor packages are integrated ever more highly and more densely so as to work at very high frequencies. In a semiconductor package that operates at frequencies in excess of 1.0 GHz, therefore, it is probable that the semiconductor element will malfunction because the Ni-plated layer, which is the intermediate layer, is a ferromagnetic material on the lead frame made of a base material of copper or a copper alloy plated with Pd or a Pd alloy. That is, for a semiconductor element that operates at a very high frequency, the presence of a ferromagnetic material such as Ni in the package may interrupt the operation of signals due to the magnetic field thereof.

### SUMMARY OF THE INVENTION

It is therefore an object of the present invention to provide a lead frame for a semiconductor package mounting a semiconductor element that operates at very high frequencies and which can be used in high-frequency regions without being affected by the magnetic field due to the ferromagnetic material.

According to the present invention, there is provided a lead frame for semiconductor devices provided with at least internal lead portions and external lead portions, said lead frame comprising: a base material of the lead frame consisting of copper or copper alloy; Pd or Pd alloy plated layers formed, on all surface or on at least said internal or external lead portions, through plated-under layers; and said plated-under layers consisting of a non-ferromagnetic metal in place of a Ni plated layer.

The plated under layer consisting of non-ferromagnetic metal is one selected from the group of Ag, Sn, Au and Zn plated layers.

The plated-under layer consisting of non-ferromagnetic metal is one selected from the group of Sn—Ag and Sn—Zn alloy plated layers.

The plated-under layer comprises a first plated-under layer consisting of a first non-ferromagnetic metal and a second plated-under layer consisting of a second non-ferromagnetic metal which is different from said first non-ferromagnetic metal.

The first plated-under layer and the second plated-under layer are a combination of the selected one from the group of an Sn plated layer and an Ag plated layer, an Ag plated layer and an Sn plated layer, an Ag plated layer and an Au plated layer, and an Sn plated layer and an Au plated layer.

### BRIEF DESCRIPTION OF THE DRAWINGS

FIG. 1 is a cross-sectional view showing a plated structure of according to the present invention;

FIG. 2 is a cross-sectional view showing another embodiment of a plated structure of a lead frame according to the present invention;

FIG. 3 is a plan view of a lead frame for semiconductor devices; and

FIG. 4 is a cross-sectional view showing a plated structure of a lead frame known in the prior art.

### DETAILED DESCRIPTION OF THE PREFERRED EMBODIMENTS

Preferred embodiments of the invention will now be described in detail with reference to the accompanying drawings.

The lead frame for a semiconductor package according to the present invention is the one made of a base material of copper or a copper alloy and has its all surfaces, or partial surfaces, i.e. at least internal lead portions or external lead portions, plated with Pd or a Pd alloy. The lead frame for a semiconductor package according to the invention has a feature in the structure in which a base material of copper or a copper alloy is plated with a non-ferromagnetic metal and is further plated with Pd or a Pd alloy with the non-ferromagnetic metal-plated layer as an underlying layer.

Here, the ferromagnetic metal is a metal, such as Fe, Co, or Ni which is strongly influenced and, thus, magnetized by the magnetic field and, even if the magnetic field is removed, the magnetized condition remains. The magnetic susceptibility of ferromagnetic metal is as follows.

| | | |
|---|---|---|
| Fe: | 217.6 | Gcm³/g |
| Co: | 161.85 | Gcm³/g |
| Ni: | 55.07 | Gcm³/g |

On the other hand, the magnetic susceptibility of non-ferromagnetic metal, which is suitable to be used as an under layer in place of Ni-plated layer according to this invention, is as follows.

| | | |
|---|---|---|
| Ag: | −0.192 | Gcm³/g |
| Au: | −0.142 | Gcm³/g |
| Sn: | −0.25 | Gcm³/g |
| Zn: | −0.174 | Gcm³/g |

The magnetic susceptibility of the main other metal is as follows.

| | | |
|---|---|---|
| Al: | 0.61 | Gcm³/g |
| Cu: | −0.086 | Gcm³/g |
| Pd: | 5.15 | Gcm³/g |
| Cr: | 3.5 | Gcm³/g |
| Cd: | −0.175 | Gcm³/g |

### EXAMPLE 1

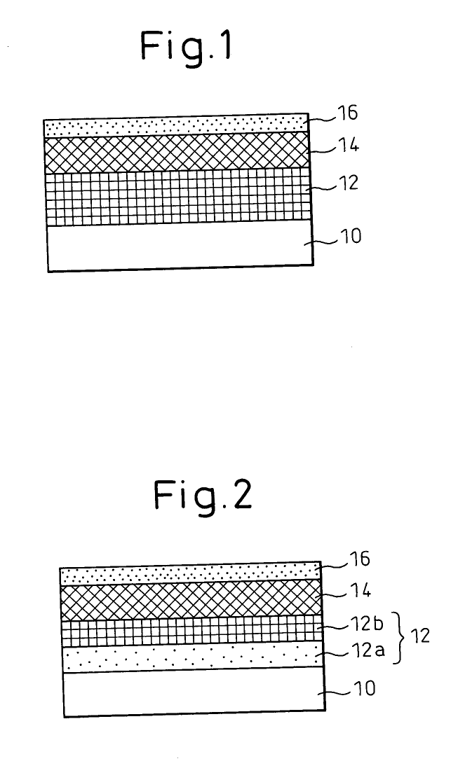

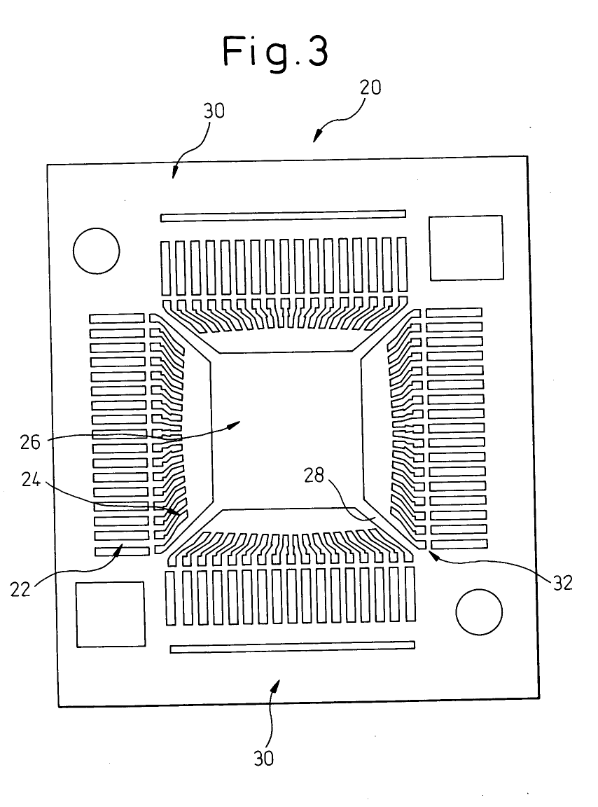

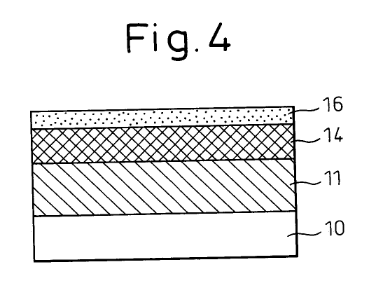

FIG. 1 is a view of a lead frame for a semiconductor package according to the invention, and illustrates a constitution of layers plated on the surface of a base material of copper or a copper alloy.

In FIG. 1, reference numeral 10 denotes a base material of copper or a copper alloy, 12 denotes an underlying plated layer of a non-ferromagnetic metal, 14 denotes a Pd-plated layer, and 16 denotes an Au-plated layer. In this Example, an Ag layer is plated as the underlying plated layer 12 of a non-ferromagnetic metal. The underlying plated layer 12, Pd-plated layer 14 and Au-plated layer 16 are all formed on the whole surface of the base material 10.

In this Example, the plated layers have thicknesses as described below.

The underlying plated layer (Au-plated layer): 0.0003 to 5 μm, preferably, 0.1 to 2 μm

Pd-plated layer: 0.001 to 0.10 μm, preferably, 0.01 to 0.03 μm

Au-plated layer: 0.001 to 0.03 μm, preferably, 0.003 to 0.005 μm

As copper or a copper alloy used as the base material 10, there can be used copper or a copper alloy not containing a ferromagnetic metal, such as pure copper, a copper-tin alloy or a copper-zinc alloy.

According to the lead frame for a semiconductor package constituted according to this Example, it is made possible to obtain intimate adhesion between the base material 10 and the Pd-plated layer 14 like that of the conventional lead frame having the Ni-plated layer under the Pd-plated layer and, hence, to obtain a required heat resistance and corrosion resistance. Due to the action and effect of the Pd-plated layer 14, further, a good soldering property is obtained. In particular, the semiconductor package of this embodiment does not at all include a ferromagnetic metal in the plated layer preventing the operation of the semiconductor element from being impaired by the magnetic field in the high-frequency region that is caused by the semiconductor package itself. Further, the lead frame for a semiconductor package of this embodiment offers an advantage of easily controlling the plating.

### EXAMPLE 2

The lead frame for a semiconductor package according to this Example has a feature in that an Sn-layer is plated as an underlying plated layer 12 on the surface of the base material 10 of copper or a copper alloy. The plated layers have thicknesses as described below.

The underlying plated layer (Sn-plated layer): 0.0003 to 10 μm, preferably, 0.1 to 0.5 μm

Pd-plated layer: 0.001 to 0.10 μm, preferably, 0.01 to 0.04 μm

Au-plated layer: 0.001 to 0.03 μm, preferably, 0.003 to 0.005 μm

The lead frame for a semiconductor package of this Example, too, makes it possible to obtain heat resistance and corrosion resistance same as those of the conventional lead frame having the Ni-plated layer as the underlying layer. Further, the cost of production is the same as that of when the Ni-layer is plated as the underlying plated layer.

### EXAMPLE 3

The lead frame for a semiconductor package according to this Example has a feature in that an Au-layer is plated as an underlying plated layer 12 on the surface of the base material 10 of copper or a copper alloy. The plated layers have thicknesses as described below.

The underlying plated layer (Au-plated layer):

0.0003 to 10 μm, preferably, 1 to 3 μm

Pd-plated layer: 0.001 to 0.10 μm, preferably, 0.01 to 0.03 μm

Au-plated layer: 0.001 to 0.03 μm, preferably, 0.003 to 0.005 μm

The lead frame for a semiconductor package having the Au-plated layer as the underlying plated layer of this Example has an advantage in that a favorable adhesion is obtained between the Pd-plated layer and copper in the base material.

### EXAMPLE 4

The lead frame for a semiconductor package according to this Example has a feature in that a Zn-layer is plated as an underlying plated layer 12 on the surface of the base material 10 of copper or a copper alloy. The plated layers have thicknesses as described below.

The underlying plated layer (Zn-plated layer): 0.0003 to 5 μm, preferably, 0.1 to 0.5 μm

Pd-plated layer: 0.001 to 0.10 μm, preferably, 0.005 to 0.03 μm

Au-plated layer: 0.001 to 0.03 μm, preferably, 0.003 to 0.005 μm

The lead frame for a semiconductor package of this Example has heat resistance and corrosion resistance superior to those obtained when Ni is plated as the underlying layer. The cost of production is suppressed, too, which is an advantage.

### EXAMPLE 5

In the lead frame for a semiconductor package according to this Example, the underlying plated layer 12 formed on the surface of the base material 10 of copper or a copper alloy has a two-layer structure including, as shown in FIG. 2, a first underlying plated layer 12a and a second underlying plated layer 12b of non-ferrous metals.

In this Example, Sn is plated as the first underlying plated layer 12a and Ag is plated as the second underlying plated layer 12b. The plated layers have thicknesses as described below.

The first underlying plated layer (Sn-plated layer): 0.0003 to 5 μm, preferably, 0.1 to 0.5 μm

The second underlying plated layer (Ag-plated layer):

0.0003 to 5 μm, preferably, 0.5 to 1 μm

Pd-plated layer: 0.001 to 0.10 μm, preferably, 0.005 to 0.03 μm

Au-plated layer: 0.001 to 0.03 μm, preferably, 0.003 to 0.005 μm

The lead frame for a semiconductor package of this Example exhibits improved heat resistance and corrosion resistance, and offers an advantage of improved adhesion between the Pd-plated layer and copper in the base material.

### EXAMPLE 6

In the lead frame for a semiconductor package according to this Example, the underlying plated layer 12 has a two-layer structure, i.e., an Ag-plated layer as the first underlying plated layer 12a and an Sn-plated layer as the second underlying plated layer 12b. The plated layers have thicknesses as described below.

The first underlying plated layer (Ag-plated layer): 0.0003 to 5 μm, preferably, 0.5 to 1 μm

The second underlying plated layer (Sn-plated layer):

0.0003 to 10 μm, preferably, 0.1 to 0.5 μm

Pd-plated layer: 0.001 to 0.10 μm, preferably, 0.01 to 0.04 μm

Au-plated layer: 0.001 to 0.03 μm, preferably, 0.003 to 0.005 μm

The lead frame for a semiconductor package of this Example exhibits improved heat resistance and corrosion resistance, and makes it possible to improve adhesion between the Pd-plated layer and copper in the base material.

### EXAMPLE 7

In the lead frame for a semiconductor package according to this Example, the underlying plated layer 12 has a two-layer structure, i.e., an Ag-plated layer as the first underlying plated layer 12a and an Au-plated layer as the second underlying plated layer 12b. The plated layers have thicknesses as described below.

The first underlying plated layer (Ag-plated layer): 0.0003 to 5 μm, preferably, 1.0 to 1.5 μm

The second underlying plated layer (Au-plated layer):

0.0003 to 10 μm, preferably, 0.005 to 0.01 μm

Pd-plated layer: 0.001 to 0.10 μm, preferably, 0.01 to 0.04 μm

Au-plated layer: 0.001 to 0.03 μm, preferably, 0.003 to 0.005 μm

The lead frame for a semiconductor package of this Example exhibits improved heat resistance and corrosion resistance.

### EXAMPLE 8

In the lead frame for a semiconductor package according to this Example, the underlying plated layer 12 has a two-layer structure, i.e., an Sn-plated layer as the first underlying plated layer 12a and an Au-plated layer as the second underlying plated layer 12b. The plated layers have thicknesses as described below.

The first underlying plated layer (Sn-plated layer):

0.0003 to 10 μm, preferably, 0.5 to 1 μm

The second underlying plated layer (Au-plated layer):

0.0003 to 10 μm, preferably, 0.005 to 0.01 μm

Pd-plated layer: 0.001 to 0.10 μm, preferably, 0.05 to 0.03 μm

Au-plated layer: 0.001 to 0.03 μm, preferably, 0.003 to 0.005 μm

The lead frame for a semiconductor package of this Example exhibits improved heat resistance and corrosion resistance, and makes it possible to improve adhesion among the underlying plated layer, the Pd-plated layer and copper in the base material.

### EXAMPLE 9

The lead frame for a semiconductor package according to this Example has a feature in that the underlying plated layer 12 is formed on the surface of the base material 10 of copper or a copper alloy, the underlying plated layer 12 being an Sn/Au plated layer of an alloy of Sn and Au. The plated layers have thicknesses as described below.

The underlying plated layer (Sn/Au plated layer):

0.0003 to 5 μm, preferably, 0.5 to 1 μm

Pd-plated layer: 0.001 to 0.10 μm, preferably, 0.005 to 0.03 μm

Au-plated layer: 0.001 to 0.03 μm, preferably, 0.003 to 0.005 μm

The lead frame for a semiconductor package of this Example exhibits improved heat resistance and corrosion resistance, and makes it possible to improve adhesion among the underlying plated layer, the Pd-plated layer and copper in the base material.

### EXAMPLE 10

The lead frame for a semiconductor package according to this Example has a feature in that the underlying plated layer 12 is formed on the surface of the base material 10 of copper or a copper alloy, the underlying plated layer 12 being an Sn/Zn plated layer of an alloy of Sn and Zn. The plated layers have thicknesses as described below.

The underlying plated layer (Sn/Zn plated layer):

0.0003 to 5 μm, preferably, 0.5 to 1 μm

Pd-plated layer: 0.001 to 0.10 μm, preferably, 0.005 to 0.03 μm

Au-plated layer: 0.001 to 0.03 μm, preferably, 0.003 to 0.005 μm

The lead frame for a semiconductor package of this Example exhibits improved heat resistance and corrosion resistance.

Like the conventional lead frame having the Ni-plated layer formed under the Pd-plated layer, when heated, the above-mentioned lead frames for semiconductor packages of Examples 2 to 10 prevent copper in the base material 10 of copper or a copper alloy from being diffused in the surface of the lead frame owing to the underlying plated layer 12, exhibit improved adhesion between the base material 10 and the Pd-plated layer 14, to maintain heat resistance and solder wettability relying upon the Pd-plated layer 14. Thus, there are provided lead frames enabling the Pb-free mounting.

In the lead frames of the above-mentioned Examples, further, ferromagnetic metals such as Ni and the like are not used in the base material of the lead frame or in the plated layers. Therefore, the lead frames are preferably used for mounting the semiconductor elements used in high-frequency regions such as of 1 GHz.

In the lead frames for semiconductor packages according to the invention as described above, ferromagnetic metals such as Ni and the like are used in neither the base material of the lead frames nor the layers plated on the surface of the base material. Therefore, the lead frames are preferably used for mounting the semiconductor elements used in high-frequency regions. Besides, as the Pd layer is plated on the whole surface of the base material, there are provided lead frames that are easy to handle offering required soldering property, heat resistance and corrosion resistance.

It should be understood by those skilled in the art that the foregoing description relates to some of the preferred embodiments or examples of the disclosed invention, and that various changes and modifications may be made to the invention without departing the sprit and scope thereof.

1. A lead frame, for semiconductor devices, provided with at least internal lead portions and external lead portions, said lead frame comprising:
a base material of the lead frame consisting of copper or copper alloy;
Pd or pd alloy plated layers formed, on all surface or on at least said internal or external lead portions, through plated under layers; and
said plated-under layers consisting of non-ferromagnetic metal in place of Ni plated layer:

2. A lead frame, as set forth in claim 1, wherein said plated-under layer consisting of non-ferromagnetic metal is one selected from the group of Ag, Sn, Au and Zn plated layers.

3. A lead frame as set forth in claim 1, wherein said plated-under layer consisting of non-ferromagnetic metal is one selected from the group of Sn—Ag and Sn—Zn alloy plated layers.

4. A lead frame as set forth in claim 1, wherein said plated-under layer comprises a first plated-under layer consisting of a first non-ferromagnetic metal and a second plated-under layer consisting of a second non-ferromagnetic metal which is different from said first non-ferromagnetic metal.

5. A lead frame as set forth in claim 4, wherein said first plated-under layer and said second plated-under layer are a combination of a selected one from the group of Sn plated layer and Ag plated layer, Ag plated layer and Sn plated layer, Ag plated layer and Au plated layer, and Sn plated layer and Au plated layer.
